(19) United States
(12) Patent Application Publication
(10) Pub. No.: US 2025/0031554 A1
(43) Pub. Date: Jan. 23, 2025

(54) LIGHT EMITTING DISPLAY DEVICE AND METHOD OF MANUFACTURING THE SAME

(71) Applicant: LG Display Co., Ltd., Seoul (KR)

(72) Inventor: Sung Ji YOON, Paju-si (KR)

(73) Assignee: LG Display Co., Ltd., Seoul (KR)

(21) Appl. No.: 18/773,140

(22) Filed: Jul. 15, 2024

(30) Foreign Application Priority Data
Jul. 21, 2023 (KR) 10-2023-0095428

(51) Int. Cl. H10K 59/80; H10K 59/12

(52) U.S. Cl. CPC H10K 59/879; H10K 59/1201

(57) ABSTRACT

A light emitting display device in one example includes a substrate having a first sub-pixel and a second sub-pixel, a light emitting element provided on the substrate, a first capping layer provided on a second electrode of the light emitting element, a metal pattern provided on the first capping layer and corresponding to the first sub-pixel, and a refractive pattern provided on the first capping layer and corresponding to the second sub-pixel.

### CROSS-REFERENCE TO RELATED APPLICATIONS

This application claims priority to Korean Patent Application No. 10-2023-0095428, filed in the Republic of Korea on Jul. 21, 2023, the entire contents of which is hereby expressly incorporated by reference into the present application.

### BACKGROUND OF THE INVENTION

### Field of the Invention

The present disclosure relates to a light emitting display device, and more particularly, to a light emitting display device that is capable of reducing a steep change in luminance depending on the viewing angle and a method of manufacturing the light emitting display device.

### Discussion of the Related Art

With the advent of the information society, displays for visually expressing electrical information signals have developed rapidly. In response to this, research is underway on development of various display devices with excellent performance such as slimness, reduced weight, and lower power consumption.

Among such display devices, a light emitting display device includes a light emitting element spontaneously capable of emitting light and thus does not require a separate light source used in a non-light emitting element, thus realizing reduced weight and thickness.

The light emitting element includes an intermediate layer between a first electrode and a second electrode, and emits light when an electric field is applied between the first and second electrodes.

The light emitted from the intermediate layer spreads toward the front, back and side surfaces, and the first electrode is formed of a reflective electrode, thus eventually allowing the light to travel to the front and side surfaces. The emitted light traveling to the side surface may not be emitted by a structure such as a bank and can be trapped inside. Such a light emitting display device can have a limitation in which the luminance of the side surface can decrease quickly compared to the front surface depending on the viewing angle of the viewer.

### SUMMARY OF THE INVENTION

Accordingly, the disclosure is directed to a light emitting display device that substantially obviates one or more problems due to the limitations and disadvantages of the related art.

It is an object of the present disclosure to provide a light emitting display device that is capable of selectively reducing the microcavity effect of sub-pixels and reducing the luminance deviation between the front and side surfaces, thereby reducing a rapid change in luminance depending on the viewing angle.

Additional advantages, objects, and features of the disclosure will be set forth in part in the description which follows and in part will become apparent to those having ordinary skill in the art upon examination of the following, or can be learned from practice of the disclosure. The objectives and other advantages of the disclosure can be realized and attained by the structure particularly pointed out in the written description and claims hereof as well as the appended drawings.

The light emitting display device according to one or more aspects of the present disclosure has a refractive pattern on the second electrode of the selected sub-pixel and has a metal pattern on the second electrode of sub-pixels other than the selected sub-pixel, thereby reducing the microcavity effect of the selected sub-pixel.

In addition, the light emitting display device according to one or more aspects of the present disclosure further includes a metal pattern on the refractive pattern of the selected sub-pixel and makes the metal pattern of the selected sub-pixel thinner than the metal pattern of the other sub-pixels, thereby reducing the microcavity effect of the selected sub-pixel.

A light emitting display device according to an the present disclosure includes a substrate embodiment of including a first sub-pixel and a second sub-pixel, a light emitting element on the substrate, a first capping layer provided on a second electrode of the light emitting element, a metal pattern provided on the first capping layer and corresponding to the first sub-pixel, and a refractive pattern provided on the first capping layer and corresponding to the second sub-pixel.

It is to be understood that both the foregoing general description and the following detailed description of the disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a cross-sectional view illustrating a light emitting display device according to a first embodiment of the present disclosure;

FIG. 2 is a graph showing a luminance viewing angle;

FIGS. 3A to 3D are cross-sectional views illustrating a process of manufacturing the light emitting display device of FIG. 1; and

FIG. 4 is a cross-sectional view illustrating a light emitting display device according to a second embodiment of the present disclosure.

### DETAILED DESCRIPTION OF THE EMBODIMENTS

The advantages and features of the present disclosure and methods of accomplishing the same will be clearly understood from the following preferred embodiments with reference to the attached drawings. However, the present disclosure is not limited to the embodiments, and can be embodied in different forms. The embodiments are suggested only to offer a thorough and complete understanding of the disclosed context and to sufficiently inform those skilled in the art of the technical concept of the present disclosure and embodiments of the present disclosure are only defined by the scope of the claims.

The shape, size, ratio, angle, number, and the like shown in the drawings to illustrate various embodiments of the present disclosure are merely provided for illustration, and the disclosure is not limited to the content shown in the drawings. Wherever possible, the same reference numbers will be used throughout the drawings to refer to the same or like parts. In the following description, detailed descriptions of technologies or configurations related to the present disclosure can be omitted so as to avoid unnecessarily obscuring the subject matter of the present disclosure.

When terms such as “including”, “having”, and “comprising” are used throughout the disclosure, an additional component can be present, unless “only” is used. A component described in a singular form encompasses a plurality thereof unless particularly stated otherwise.

The components included in the embodiments of the present disclosure should be interpreted to include an error range, even if there is no additional particular description thereof.

In describing the variety of embodiments of the present disclosure, when terms describing positional relationships such as “on”, “above”, “under” and “next to” are used, at least one intervening element can be present between the two elements, unless “immediately” or “directly” is also used.

In describing the variety of embodiments of the present disclosure, when terms related to temporal relationships, such as “after”, “subsequently”, “next”, and “before”, are used, the non-continuous case can be included, unless “immediately” or “directly” is also used.

In describing the variety of embodiments of the present disclosure, terms such as “first” and “second” can be used to describe a variety of components, but these terms only aim to distinguish the same or similar components from one another and may not define order or sequence. Accordingly, throughout the disclosure, a “first” component can be the same as a “second” component within the technical concept of the present disclosure, unless specifically mentioned otherwise.

The terms such as “first horizontal axis direction”, “second horizontal axis direction”, and “vertical axis direction” should not be interpreted as only geometric relationships in which the relationship between each other is vertical, and as having a broader range of direction as long as the configuration of the present disclosure can serve functionally.

The term “at least one” should be understood to include all possible combinations of one or more related items. For example, “at least one of the first, second, and third items” means each of the first, second, or third items, as well as any combination of two or more of the first, second, and third items.

Features of various embodiments of the present disclosure can be partially or completely coupled to or combined with each other, and can be variously inter-operated with each other and driven technically. The embodiments of the present disclosure can be carried out independently from each other, or can be carried out together in an interrelated manner.

In adding reference numerals to components in each drawing, identical components can have the same reference numerals as much as possible even if they are shown in different drawings. In addition, the scale of the components shown in the attached drawings has a different scale from the actual scale for convenience of explanation and is thus not limited to the scale shown in the drawings.

Further, the term “can” encompasses all the meanings and coverages of the term “may.” Also, all the components of each display device or apparatus according to all embodiments of the present disclosure are operatively coupled and configured.

Hereinafter, an example of a light emitting display device according to various embodiments of the present disclosure will be described in detail with reference to the attached drawings.

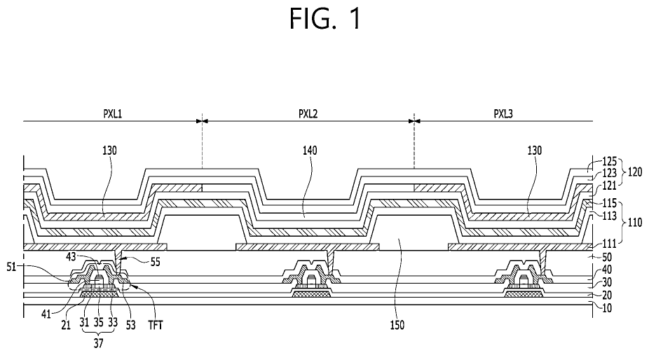

FIG. 1 is a cross-sectional view illustrating a light emitting display device according to a first embodiment of the present disclosure.

Referring to FIG. 1, the light emitting display device according to the first embodiment of the present disclosure includes a substrate 10 including a plurality of sub-pixels PXL1, PXL2, and PXL3, a thin film transistor TFT on the substrate 10, a light emitting element 110 on the thin film transistor TFT, a capping layer structure 120 including a first capping layer 121, a second capping layer 123, and a third capping layer 125 on the light emitting element 110, and a refractive pattern 140 and a metal pattern 130 provided in the same layer between the first capping layer 121 and the second capping layer 123. Here, the refractive pattern 140 can be provided in the area corresponding to the second sub-pixel PXL2, and the metal pattern 130 can be provided in the first and third sub-pixels PXL1 and PXL3 where the refractive pattern 140 is not provided.

The substrate 10 is divided into a display area where the screen appears and a peripheral area where the screen does not appear, and the display area can include a plurality of sub-pixels PXL1, PXL2, and PXL3 repeatedly arranged. The sub-pixels PXL1, PXL2, and PXL3 can include a light emitting portion where light is actually emitted, and a non-light emitting area where light is not emitted around the light emitting portion. For example, when the substrate 10 is a plastic substrate, it can contain polyimide or polyamide.

The sub-pixels PXL1, PXL2, and PXL3 can be defined by gate lines and data lines that are formed in a matrix form while intersecting each other on a substrate within the display area. The sub-pixels PXL1, PXL2, and PXL3 can include first to third sub-pixels PXL1, PXL2, and PXL3 that emit different colors. The first sub-pixel PXL1 can emit red light, the second sub-pixel PXL2 can emit green light, and the third sub-pixel PXL3 can emit blue light. In addition, the plurality of sub-pixels PXL1, PXL2, and PXL3 can further include a sub-pixel that emits white light.

On the substrate 10, various signal wires such as data signal wires and gate signal wires, transistors such as switching thin film transistors and driving thin film transistors, and circuit elements including capacitors can be formed in respective sub-pixels PXL1, PXL2, and PXL3. For convenience of description, a single thin film transistor TFT driving one light emitting portion can be provided.

A thin film transistor TFT includes an active layer 37, a gate electrode 43 overlapping the channel region 35 of the active layer 37 with a gate insulating film 41 therebetween, and a source electrode 51 and a drain electrode 53 connected to both sides of the active layer 37.

The active layer 37 of the thin film transistor TFT includes a source region 31 and a drain region 33 on both sides thereof with a channel region 35 therebetween. Each of the source region 31 and the drain region 33 is formed of a semiconductor material doped with n-type or p-type impurities. The channel region 35 overlapping the gate electrode 43 can be formed of a semiconductor material not doped with n-type or p-type impurities.

The gate electrode 43 of the thin film transistor TFT is provided to overlap the channel region 35 of the active layer 37, while having the same width as the channel region 35, with the gate insulating film 41 interposed therebetween. The gate insulating film 41 overlaps the channel region 35 of the active layer 37 in the same pattern as the gate electrode 43. For example, the gate electrode 43 can be a single layer or multiple layers containing one of molybdenum (Mo), aluminum (Al), chromium (Cr), gold (Au), titanium (Ti), nickel (Ni), neodymium (Nd), and copper (Cu), or an alloy thereof. Meanwhile, the gate insulating film 41 can contain an inorganic insulating material, and can include, for example, a silicon oxide film (SiOx), a silicon nitride film (SiNx), a silicon oxynitride film (SiOxNy), or multiple films thereof.

Meanwhile, the light-blocking layer 21 on the substrate 10 overlaps at least the channel region 35 of the active layer 37 of the thin film transistor TFT and is disposed below the active layer 37. The light-blocking layer 21 prevents external light from penetrating the substrate 10 and being transmitted to the thin film transistor TFT. For example, the light-blocking layer 21 can be a single layer containing a metal material such as molybdenum (Mo), titanium (Ti), aluminum-neodymium (AlNd), aluminum (Al), chromium (Cr), or an alloy thereof, or a multilayer structure using the same.

The buffer film 20 on the light-blocking layer 21 is provided to cover the light-blocking layer 21. For example, the buffer film 20 can have a single-layer or multilayer structure containing silicon oxide (SiOx) or silicon nitride (SiNx).

The interlayer insulating film 30 on the buffer film 20 includes a source contact hole and a drain contact hole exposing each of the source region 31 and the drain region 33 of the active layer 37, and covers the gate insulating film 41 and the gate electrode 43. For example, the interlayer insulating film 30 can contain an inorganic insulating material. For example, the interlayer insulating film 30 can be a single layer or multiple layers of a silicon oxide film (SiOx), a silicon nitride film (SiNx), or a silicon oxynitride film (SiOxNy).

The source electrode 51 and the drain electrode 53 can be provided in the same layer on the interlayer insulating film 30. Each of the source electrode 51 and the drain electrode 53 is connected to the source region 31 and drain region 33 of the active layer 37 through a source contact hole and a drain contact hole. For example, the source electrode 51 and the drain electrode 53 can be a single layer containing a metal material such as molybdenum (Mo), aluminum (Al), chromium (Cr), gold (Au), titanium (Ti), nickel (Ni), neodymium (Nd), copper (Cu), or an alloy thereof, or a multilayer structure using the same.

The passivation layer 40 on the interlayer insulating film 30 can be provided to cover a region of the thin film transistor TFT. As a result, the thin film transistor TFT can be protected by the passivation layer 40. For example, the passivation layer 40 is a type of inorganic insulating film and can be provided as a single layer or multiple layers of a silicon oxide film (SiOx), a silicon nitride film (SiNx), or a silicon oxynitride film (SiOxNy).

A planarization layer 50 can be provided on the passivation layer 40. The planarization layer 50 is formed to a thickness sufficient to planarize the surface step at the top of the thin film transistor TFT and can be formed of an organic insulating film. In some cases, when the planarization layer 50 also functions to protect the thin film transistor TFT, the passivation layer 40 can be omitted. For example, the planarization layer 50 is a type of organic insulating film and can be any one of photoacryl, polyimide, benzocyclobutene resin, and acrylate. In some cases, the planarization layer 50 can be formed in multiple layers.

A light emitting element 110 including a stack structure of a first electrode 111, an intermediate layer 113, and a second electrode 115 can be provided on the planarization layer 50. The first electrode 111 of the light emitting element 110 can be provided in each of the plurality of sub-pixels PXL1, PXL2, and PXL3 and can be connected to the thin film transistor TFT through the contact hole 55. The light emitting element 110 can be operated based on the mechanism in which, when current is supplied from the power voltage line to the second electrode 115 and a high-voltage current is supplied from the thin film transistor TFT to the first electrode 111, an electric field is formed between the first electrode 111 and the second electrodes 115, and the intermediate layer 113 emits light.

The light emitting device 110 can be formed in a top-emission, bottom-emission, or dual-emission manner depending on the structure thereof. The light emitting display device according to the present disclosure can be formed in a top emission manner in which the first electrode 111 is used as an electrode with high reflection efficiency to emit light in the direction opposite to the substrate 10.

Accordingly, the first electrode 111 can be formed in a multilayer structure including a transparent conductive film and an opaque conductive film with high reflection efficiency. The transparent conductive film of the first electrode 111 contains a material with a relatively high work function value such as indium tin oxide (ITO) or indium zinc oxide (IZO), and the opaque conductive film can be a single layer containing any one selected from the group consisting of silver (Ag), aluminum (Al), copper (Cu), molybdenum (Mo), titanium (Ti), nickel (Ni), chromium (Cr), tungsten (W), and an alloy thereof, or multiple layers. When the first electrode 111 is formed as a transparent conductive film made of a material with a relatively high work function that contacts the intermediate layer 113, hole injection from the first electrode 111 to the intermediate layer 113 can be easy. For example, the first electrode 111 can have a structure in which a transparent conductive film, an opaque conductive film, and a transparent conductive film are sequentially stacked, or a structure in which a transparent conductive film and an opaque conductive film are sequentially stacked.

The second electrode 115 opposite to the first electrode 111 can be formed over the entire substrate 10 on the intermediate layer 113 through a common mask. For example, the second electrode 115 can be made of a transparent conductive material such as indium tin oxide (ITO) or indium zinc oxide (IZO), and can be made of silver (Ag), aluminum (Al), magnesium (Mg) or calcium (Ca) having a thickness small enough to transmit light, or an alloy thereof. Here, in order for the light emitting display device according to the present disclosure to have a microcavity effect, the second electrode 115 can be formed as a transflective electrode that transmits some light while reflecting other light. The second electrode 115 can be formed as a transflective electrode having a higher transmittance than the first electrode 111. In other words, the second electrode 115 of the light emitting display device according to the present disclosure is made of silver (Ag), aluminum (Al), magnesium (Mg), or calcium (Ca) having a thickness sufficient to transmit light, or an alloy thereof.

The first electrode 111 and the second electrode 115 can reflect light generated from the intermediate layer 113 several times and induce destructive interference and constructive interference between the reflected light. As a result of destructive and constructive interference, a microcavity effect, the phenomenon in which only light of a predetermined wavelength is maintained and the intensity of light of other wavelengths is weakened, can occur. The microcavity effect occurs when the inherent vibration of the light emitting layer provided in each sub-pixel and the optical length between the first electrode 111 and the second electrode 115, for example, the thickness of the intermediate layer 113, match. Here, the optical length can vary depending on not only the thickness of the intermediate layer 113 but also components having different refractive indices provided on the second electrode 115. For example, the optical length can be adjusted by components such as the capping layer structure 120 including a first capping layer 121, a second capping layer 123, and a third capping layer 125 on the second electrode 115, and the refractive pattern 140 or the metal pattern 130. Accordingly, the light emitting display device according to the present disclosure can increase or adjust the microcavity effect by adjusting the optical length, and has the effect of improving light emission efficiency, such as increasing brightness.

In addition, among the light generated in the intermediate layer 113, the light traveling to the side surface is trapped inside by a structure such as the bank 150 in the light emitting element 110, so the luminance on the side surface can be low compared to the front surface. In particular, the luminance of the front and side surfaces can be increased by the microcavity effect caused by the first electrode 111 and the second electrode 115, respectively. As a result, the difference in luminance between the front and the side surfaces can be maximized, and the luminance can drop sharply toward the side surface. In addition, changes in luminance can make changes in color by causing changes in the brightness of the color itself. For example, in a light emitting display device, the microcavity effect can affect the luminance viewing angle and the color viewing angle depending on the luminance viewing angle due to the structure within the light emitting device 110.

Here, the light emitting display device according to the present disclosure has the metal pattern 130 and the refractive pattern 140 selectively provided in each sub-pixel through the first capping layer 121 interposed on the second electrode 115 of the light emitting element 110 in order to minimize the luminance and color difference between the front and side surfaces. The refractive pattern 140 can be provided in the second sub-pixel PXL2, and the metal pattern 130 can be provided in the first and third sub-pixels PXL1 and PXL3 without the refractive pattern 140, but the present disclosure is not limited thereto. The refractive pattern 140 can be provided instead of the metal pattern 130 in the first and third sub-pixels PXL1 and PXL3 if it affects luminance reduction as follows. In addition, although FIG. 1 shows that the refractive pattern 140 and the metal pattern 130 have the same thickness, thicknesses thereof can be different as necessary. The refractive pattern 140 and the metal pattern 130 can have different thicknesses depending on the predetermined refractive index in each sub-pixel.

For example, the refractive pattern 140 can include an organic material having a higher transmittance than the second electrode 115, and the metal pattern 130 can be made of the same material as the second electrode 115 or can be made of a metal having the same transmittance as the second electrode 115. The metal pattern 130 can reflect light emitted from the intermediate layer 113, thereby providing a microcavity effect with each of the first electrode 111 and the second electrode 115. In other words, when the light emitting display device according to the present disclosure has the metal pattern 130, it can increase the amount of light that can be vacuumed to provide the microcavity effect, thereby improving the microcavity effect compared to when only the first and second electrodes 111 and 115 are provided. On the other hand, the refractive pattern 140 has a predetermined refractive index and can reflect some of the light emitted from the intermediate layer 113, but compared to the metal pattern 130, it transmits more light than it reflects and reduces a microcavity effect.

The second sub-pixel PXL2 selected to have the refractive pattern 140 can be present in a relatively high proportion with respect to all sub-pixels. For example, the first to third sub-pixels PXL1, PXL2, and PLX3 can emit light of one of red, green, and blue colors, respectively. The second sub-pixel PXL2 selected to have the refractive pattern 140 can emit green light. Among the three primary colors for emitting white light, green can be present in a larger proportion than red and blue. In some cases, green can be present in a proportion of 50% or more, or 60% or more, or 70% or more. In this way, the green sub-pixel, which is present in a large proportion, can be relatively well perceived by the user, and the change in luminance depending on the viewing angle can also be well perceived by the user. Accordingly, the light emitting display device according to the present disclosure selectively lowers the microcavity effect of the green sub-pixel, which is more recognizable to the user than other sub-pixels, thereby preventing the luminance of the entire sub-pixel from rapidly decreasing depending on the viewing angle. However, an example of various structures in which the light emitting display device according to the present disclosure includes a refractive pattern 140 in the second sub-pixel PXL2 and a metal pattern 130 in the first and third sub-pixels PXL1 and PXL3 is illustrated, and in some cases, the second sub-pixel PXL2 can emit light of a different color, a refractive pattern 140 can be provided in two or more sub-pixels, but the light emitting display device is not limited thereto.

In other words, the light emitting display device according to the present disclosure can have a refractive pattern 140 in the second sub-pixel PXL2, which has a relatively large influence on the decrease in luminance depending on the viewing angle, to provide a relatively low microcavity effect. As a result, the light emitting display device of the present disclosure can reduce the luminance difference between the front and side surfaces of the second sub-pixel PXL2 through the refractive pattern 140, thereby minimizing a sudden drop in luminance overall depending on the viewing angle. For example, the light emitting display device of the present disclosure can change luminance relatively consistently depending on the change in the observer's position by improvement of the luminance viewing angle. Additionally, the light emitting display device of the present disclosure can have the effect of improving the color viewing angle along with improving the luminance viewing angle.

In addition, the refractive pattern 140 can be made of an organic material with low affinity to the material of the metal pattern 130 so as to function as a mask for the metal pattern 130. Here, the fact that the refractive pattern 140 functions as a mask for the metal pattern 130 means that the metal pattern 130 can be used without a separate mask when the refractive pattern 140 is provided. For example, the refractive pattern 140 can be formed of an organic material containing an organic polymer and can contain a polycyclic aromatic compound containing at least one heteroatom of N (nitrogen), S (sulfur), O (oxygen), phosphorus (P), or aluminum (Al). The polycyclic aromatic compound can include an organic molecule including a core moiety and at least one terminal moiety bonded to the core moiety. For example, the material for the refractive pattern 140 is 3-(4-biphenyl)-4-phenyl-5-tert-butylphenyl-1,2,4-triazole (TAZ), aluminum (III) bis(2-methyl-8-quinolinato)-4-phenylphenolate (BAlq), 2-(4-(9,10-di(naphthalen-2-yl) anthracen-2-yl)phenyl)-1-phenyl-1H-benzo-[D] imidazole (LG201), 8-hydroxyquinoline lithium (Liq), and N (diphenyl-4-yl) 9,9-dimethyl-N-(4 (9-phenyl-9H-carbasol-3-yl)phenyl)-9H-fluoren-2-amine (HT211), or the like.

In this case, the refractive pattern 140 can have a low affinity for the conductive material and can have a surface that suppresses deposition of the metal pattern 130 of the conductive material. The conductive material for the metal pattern 130 can be fixed to the surface of the refractive pattern 140 according to probability through nucleation and growth processes during the deposition process. As described above, the conductive material can have a very low surface adhesion probability to the surface of the refractive pattern 140. Therefore, the conductive material can be detached from the surface of the refractive pattern 140 during the nucleation and growth process due to the low surface adhesion probability to the refractive pattern 140 and thus can be not formed.

Here, the surface adhesion probability can be measured by depositing an amount of conductive material required to form a closed-pack layer having an average thickness of 1 nm on the surface of the refractive pattern 140, in the case of depositing the conductive material. Specifically, the conductive material is simultaneously deposited on the surface of the refractive pattern 140, and the average thickness of the conductive material deposited on the substrate is compared when the average thickness of the layer concentrated on the surface of the refractive pattern 140 reaches 1 nm, to obtain the probability of surface adhesion of the conductive material for the refractive pattern 140. The probability of surface adhesion of the conductive material to the refractive pattern 140 can be at most 0.3 (or 30%) and at most 0.0008 (or 0.08%) or less. The probability of surface adhesion can be adjusted by varying the material of the refractive pattern 140, the material of the metal pattern 130, or deposition conditions. The light emitting display device according to the first embodiment does not have a metal pattern 130 on the surface of the refractive pattern 140. Accordingly, the light emitting display device according to the present disclosure can form the metal pattern 130 without a mask even if the material for the metal pattern 130 is entirely deposited on the substrate 10 provided with the refractive pattern 140.

A capping layer structure 120 can be provided on the second electrode 115. The capping layer structure 120 can include first to third capping layers 121, 123, and 125 having different refractive indices. For this purpose, each of the capping layer structures 120 can include different materials, or can have different thicknesses even if they are made of the same material. In addition, the capping layer structure 120 can prevent deterioration of the light emitting element 110 due to external moisture or oxygen. The light emitting display device according to the present disclosure includes at least one layer of the first capping layer 121, and a metal pattern 130 and a refractive pattern 140 present as the same layer are formed between the first capping layer 121 and the second capping layer 123, but the light emitting display device according to the present disclosure is not limited thereto. In some cases, the light emitting display device can include only a single first capping layer 121 or can include two, four or more layers of capping layers.

The first to third capping layers 121, 123, and 125 having different refractive indices can have a microcavity effect between the interfaces with other components. Specifically, the first to third capping layers 121, 123, and 125 have the microcavity effect at the interface between the first capping layer 121 and the second electrode 115, the interface between the first capping layer 121 and the metal pattern 130, the interface between the first capping layer 121 and the refractive pattern 140, the interface between the second capping layer 123 and the metal pattern 130, the interface between the second capping layer 123 and the refractive pattern 140, and the interface between the second capping layer 123 and the third capping layer 125. In addition, the light emitting display device according to the present disclosure can compensate for the overall luminance of the first to third sub-pixels PXL1, PXL2, and PXL3 through the capping layer structure 120. In addition, the capping layer structures 120 having different refractive indices can refract, to the side surface, light traveling toward the front surface, thereby improving the luminance viewing angle and color viewing angle.

Here, the first capping layer 121 provided on the second electrode 115 is provided between the second electrode 115 and the metal pattern 130, and improves the microcavity effect of the first and third sub-pixels PXL1 and PXL3. In addition, the first capping layer 121 can function as an insulating film for forming the metal pattern 130 and the refractive pattern 140. As described above, the refractive pattern 140 according to the first embodiment has low affinity for conductive materials, making it difficult to form the refractive pattern 140 directly on the surface of the second electrode 115 and thus providing a first capping layer 121 as an insulating film between the second electrode 115 and the refractive pattern 140. For example, the first capping layer 121 can include an organic material, an inorganic material, or a mixture thereof. Here, the inorganic material can include silicon oxide (SiOx), silicon nitride (SiNx), silicon oxynitride (SiOxNy), or the like, and the organic material can include photoacryl, polyimide, a benzocyclobutene resin, acrylate or the like, but the present disclosure is not limited thereto. The first capping layer 121 can be a capping material that has a predetermined refractive index to provide a microcavity effect and is capable of capping the light emitting element 110.

Meanwhile, the intermediate layer 113 between the first electrode 111 and the second electrode 115 can be provided on the bank 150 and the first electrode 111 exposed by the bank 150 throughout the display area. The intermediate layer 113 can refer to a single stack organic layer consisting of multiple layers including a hole injection layer (HIL), a hole transport layer (HTL), a light emitting layer (EML), an electron transport layer (ETL), and an electron injection layer (EIL). In addition, the intermediate layer 113 can include a light emitting unit with a tandem structure including a plurality of stacks (first stack and second stack), each having a light emitting layer (EML), and a charge generation layer (CGL) between the stacks. The tandem structure can have multiple stacks of two stacks or three or more stacks.

The bank 150 can be provided between the planarization layer 50 and the light emitting element 110. The bank 150 can cover a portion of the edge of the first electrode 111 and can expose the light emitting portion of the first electrode 111. Specifically, the bank 150 can cover the top and side surfaces of the edge of the first electrode 111. In addition, the bank 150 can be provided over the entire surface of non-display area and the display area excluding the light emitting portion of the first electrode 111. For example, the bank 150 can be made of an organic material such as polyimide, acrylate, or benzocyclobutene-based resin.

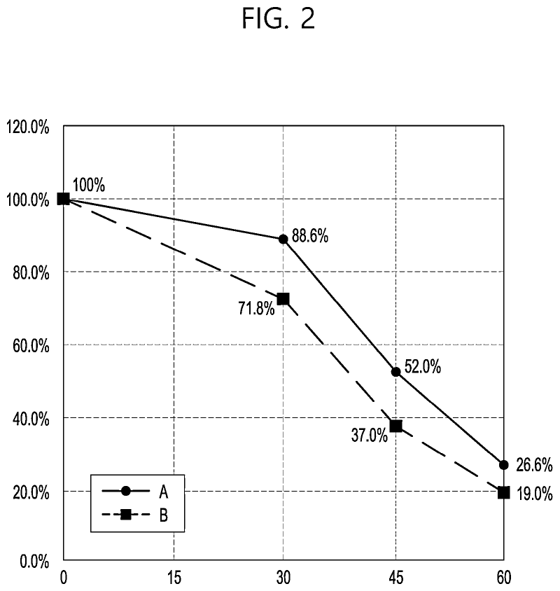

FIG. 2 is a graph showing comparison in the luminance and viewing angles between a light emitting display device (A) including the refractive pattern 140 and the metal pattern 130 selectively provided for each sub-pixel, and a light emitting display device (B) not including the refractive pattern 140 and the metal pattern 130. In the graph, the horizontal axis represents the viewing angle based on 0° of the front surface, and the vertical axis represents the luminance based on 100% of the luminance of the front surface.

Referring to FIG. 2, in the light emitting display device B in which the refractive pattern 140 and the metal pattern 130 are not provided, the luminance of sub-pixels emitting light of different colors can be substantially the same. In this case, the luminance decreases from the front surface to the side surface, especially, on the side with a viewing angle of 30°, the luminance decreases as sharply as 28.2% compared to the 100% luminance of the front surface. In other words, sub-pixels whose color gamut is far from white are sensitive to changes in luminance depending on the viewing angle (in degrees), which can cause a drastic change in luminance throughout the sub-pixels toward the side surface.

In the light emitting display device (A) in which the refractive pattern 140 and the metal pattern 130 are selectively provided for each sub-pixel, the luminance of the sub-pixels can be different from each other. For example, the microcavity effect of sub-pixels can be different. In this case, the steep change in luminance can be minimized toward the side surface. In particular, when the side viewing angle reached 30°, the luminance of the light emitting display device (A) decreased by 11.4% compared to the 100% luminance of the front surface. Compared to the light emitting display device (B) not including the refractive pattern 140 and the metal pattern 130, the light emitting display device (A) including the refractive pattern 140 and the metal pattern 130 can reduce luminance change by approximately 178, based on a side viewing angle of 30°. Accordingly, the light emitting display device according to the present disclosure includes a refractive pattern 140 in the sub-pixels that affect the luminance viewing angle and a metal pattern 130 in other sub-pixels, thereby minimizing the change in luminance depending on the viewing angle.

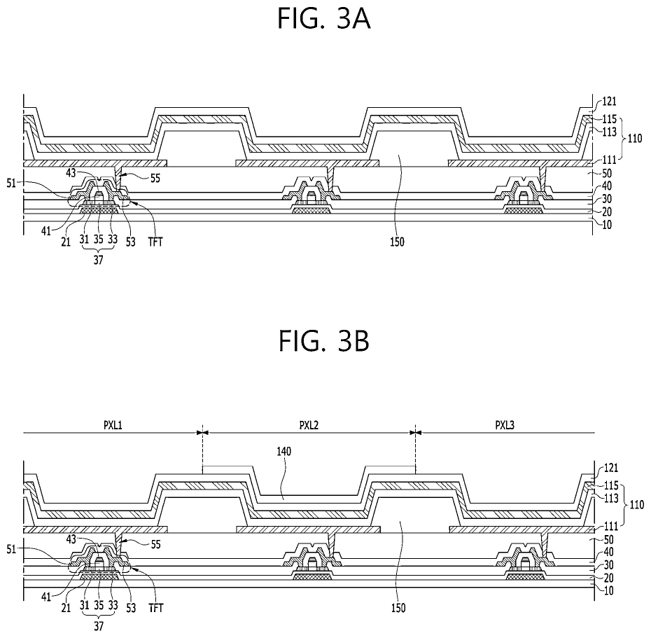

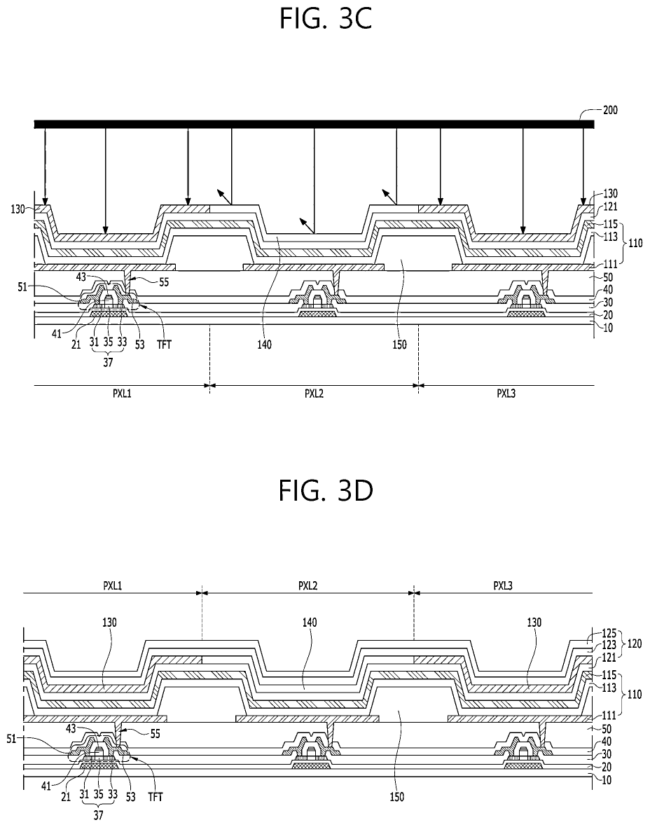

FIGS. 3A to 3D are cross-sectional views illustrating a process of manufacturing the light emitting display device of FIG. 1.

Referring to FIG. 3A, a planarization layer 50 can be formed on the substrate 10 to cover the thin film transistor TFT. Specifically, the buffer film 20 can be formed on the substrate 10 on which the light-blocking layer 21 is formed, and the active layer 37 can be formed on the buffer film 20 through a mask process. Then, the gate insulating film 41 and the gate electrode 43 can be simultaneously formed on the buffer film 20 on which the active layer 37 is formed through a mask process. Then, an interlayer insulating film 30 having source and drain contact holes can be formed on the gate electrode 43 through a mask process.

Then, source/drain electrodes 51 and 53 can be formed through a mask process on the substrate 10 on which the interlayer insulating film 30 is formed. Then, a passivation layer 40 and a planarization layer 50 having a contact hole 55 can be sequentially formed through a mask process on the interlayer insulating film 30 on which the source/drain electrodes 51 and 53 are formed.

The first electrode 111 can be formed on the planarization layer 50 in each sub-pixel through a mask process. Then, the bank 150 can be formed on the planarization layer 50 through a mask process such that it covers a portion of the edge of the first electrode 111. Then, the intermediate layer 113 and the second electrode 115 are sequentially formed over the entire surface of the substrate 10 on which the first electrode 111 and the bank 150 are formed, to form a light emitting element 110.

Then, the first capping layer 121 can be formed over the second electrode 115 such that it covers the light emitting element 110. Here, the first capping layer 121 can contain an organic material, an inorganic material, or a mixture thereof to facilitate subsequent deposition of the metal pattern 130 and the refractive pattern 140.

Referring to FIG. 3B, the refractive pattern 140 on the first capping layer 121 can be patterned into an area corresponding to the second sub-pixel PXL2. The refractive pattern 140 according to the first embodiment can be formed of an organic material with low affinity to the material for the metal pattern 130 in order for the refractive pattern 140 to function as a mask for forming the metal pattern 130. For example, the refractive pattern 140 can contain a polycyclic aromatic compound including organic molecules.

Referring to FIG. 3C, a metal pattern material 200 can be deposited over the entire surface of the substrate 10 on which the refractive pattern 140 is formed. The metal pattern material 200 reaches both the refractive pattern 140 and the first capping layer 121, but is not formed on the refractive pattern 140 due to a low probability of surface adhesion to the refractive pattern 140. That is, the metal pattern material 200 may not be adhered to the surface of the refractive pattern 140. For example, in FIG. 3C, the metal pattern material 200 that has reached the areas corresponding to the first and third sub-pixels PXL1 and PXL3 on the first capping layer 121 is fixed to form the metal pattern 130, and the metal pattern material 200 that has reached the surface of the refractive pattern 140 is not fixed and is detached. Even if the metal pattern material 200 is formed locally on the surface of the refractive pattern 140 depending on a very low surface adhesion probability, the second sub-pixel PXL2 provided with the refractive pattern 140 has almost no micro-cavity effect due to the locally formed metal pattern material 200 by selecting materials so as to prevent the metal pattern material 200 from being formed uniformly on the surface of the refractive pattern 140 according to the first embodiment. Accordingly, the light emitting display device according to the present disclosure includes the refractive pattern 140, thereby enabling formation of the metal pattern 130 without a separate mask. Therefore, the metal pattern 130 of the light emitting display device according to the present disclosure can be patterned in a more accurate position than when using a mask and can omit the mask process, which provides the effects of shortening process time and reducing production energy.

Referring to FIG. 3D, on the substrate 10 on which the metal pattern 130 and the refractive pattern 140 are formed, second and third capping layers 123 and 125 having different refractive indices can be sequentially formed on the entire surface.

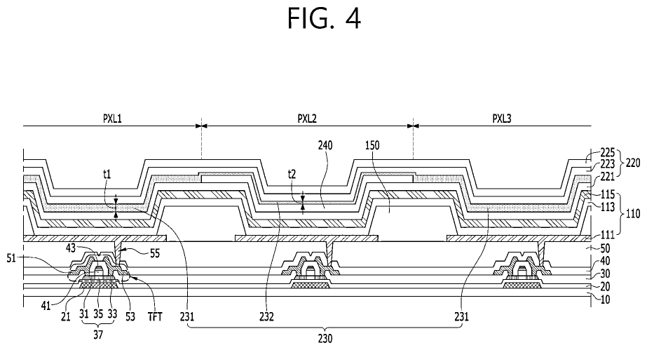

FIG. 4 is a cross-sectional view illustrating the light emitting display device according to the second embodiment of the present disclosure. Hereinafter, description of the same configuration as the previous embodiment will be omitted or may be briefly provided.

Referring to FIG. 4, the light emitting display device according to the second embodiment of the present disclosure includes a first capping layer 221, a second capping layer 223, and a third capping layer 225 on the light emitting element 110, and a refractive pattern 240 and a metal pattern 230 between the first capping layer 221 and the second capping layer 223. Here, the refractive pattern 240 can be provided in an area corresponding to the second sub-pixel PXL2. The metal pattern 230 is provided with the same thickness in the first and third sub-pixels PXL1 and PXL3 without the refractive pattern 240, and can be thinner in the second sub-pixel PXL2 than other sub-pixels PXL1 and PXL3.

The metal pattern 230 according to the second embodiment can include a first metal pattern 231 and a second metal pattern 232. The second metal pattern 232 can be provided in the second sub-pixel PXL2 where the refractive pattern 240 is selectively provided. In addition, the first metal pattern 231 can be provided in the first and third sub-pixels PXL1 and PXL3 that are not provided with the refractive pattern 240. The first metal pattern 231 and the second metal pattern 232 may not overlap each other.

The first metal pattern 231 can have a first thickness t1, and the second metal pattern 232 can have a second thickness t2 that is thinner than the first thickness t1. For example, the thickness of the metal pattern 230 corresponding to the second sub-pixel PXL2 can be thinner. In addition, the metal pattern 230 can be formed of a metal having a transmittance similar to that of the second electrode 115. Accordingly, the second metal pattern 232, which is thinner than the first metal pattern 231, can transmit more light than the light it reflects. Therefore, in the light emitting display device according to the present disclosure, the micro-cavity effect can be selectively reduced by making the second metal pattern 232 of the second sub-pixel PXL2 thinner than those of other sub-pixels. For example, the light emitting display device according to the second embodiment has the effect of improving luminance and viewing angle.

The method of manufacturing the metal pattern 230 and the refractive pattern 240 according to the second embodiment can be the same as that of the first embodiment. For example, the manufacturing method according to the second embodiment can include forming the refractive pattern 240 and then depositing the material for the metal pattern 230 over the entire surface of the refractive pattern 240. However, the metal pattern 230 and the refractive pattern 240 according to the second embodiment can include a different material from the metal pattern 130 and the refractive pattern 140 according to the first embodiment. In other words, the light emitting display device according to the second embodiment increases the probability of surface adhesion between the metal pattern 230 and the refractive pattern 240, thereby forming a second metal pattern 232 having a second thickness t2 thinner than the first thickness t1 on the refractive pattern 240. In the second embodiment, the first and second metal patterns 231 and 232 of different thicknesses can be formed through the refractive pattern 240 without a separate mask.

As such, the light emitting display device according to the present disclosure provides a refractive pattern in a sub-pixel that is sensitive to changes in luminance depending on the viewing angle and a metal pattern in other sub-pixels, thereby providing different micro-cavity effects in respective sub-pixels. In addition, the light emitting display device according to the present disclosure further includes a metal pattern on the selected refractive pattern and makes the metal pattern on the refractive pattern thinner than the metal pattern in other sub-pixels, thereby providing different micro-cavity effects in respective sub-pixels.

Accordingly, the light emitting display device according to the present disclosure can induce a gradual change in luminance from the front surface to the side surface by providing a small micro-cavity effect in the sub-pixel, which is sensitive to the change in luminance depending on the viewing angle, resulting in the effect of improving the luminance viewing angle. In addition, the light emitting display device according to the present disclosure has the effect of improving the color viewing angle through improvement in the luminance viewing angle since the luminance viewing angle is closely related to the color viewing angle.

In addition, the light emitting display device according to the present disclosure can form a metal pattern without a mask by forming the refractive pattern with a specific material, thus providing effects of shortening the process time and reducing production energy.

Meanwhile, the light emitting display device according to the present disclosure includes capping layers having different refractive indices in the capping layer structure provided on the front surface of the substrate, so that the light emitted from the light emitting layer can be refracted to the side surface, resulting in the effect of improving the luminance viewing angle and color viewing angle. In addition, the light emitting display device according to the present disclosure can provide a micro-cavity effect by adjusting the refractive index of the capping layers in the capping layer structure, thereby increasing luminous efficacy and enabling luminance compensation.

As apparent from the foregoing, the light emitting display device according to one or more aspects of the present disclosure has the following effects.

First, the light emitting display device according to one or more aspects of the present disclosure has a refractive pattern of an organic material in the second sub-pixel and a metal pattern of a metal material in the first and third sub-pixels, thereby selectively reducing the micro-cavity effect of the second sub-pixel. Accordingly, the light emitting display device according to the present disclosure has the effect of reducing rapid changes in luminance depending on the viewing angle.

Second, the light emitting display device according to one or more aspects of the present disclosure can improve the luminance viewing angle through a refractive pattern and a metal pattern, thereby improving the color viewing angle based on the luminance viewing angle.

Third, the light emitting display device according to one or more aspects of the present disclosure includes a capping layer structure on the light emitting element to protect the light emitting element, and has the effect of improving the brightness viewing angle and color viewing angle by refracting the light emitted from the light emitting element.

Fourth, the light emitting display device according to one or more aspects of the present disclosure uses a specific material for the refractive pattern to form a metal pattern without a separate mask, thereby providing the effects of shortening the process time and reducing production energy. Accordingly, the light emitting display device according to the present disclosure has ESG (environmental/social/governance) effects in terms of eco-friendliness, low power consumption, and process optimization.

A light emitting display device according to one embodiment of present disclosure can comprise a substrate comprising a first sub-pixel and a second sub-pixel, a light emitting element on the substrate, a first capping layer on a second electrode of the light emitting element, a metal pattern provided on the first capping layer and corresponding to the first sub-pixel and a refractive pattern provided on the first capping layer and corresponding to the second sub-pixel.

In a light emitting display device according to one embodiment of present disclosure, the refractive pattern can comprise an organic material.

In a light emitting display device according to one embodiment of present disclosure, the refractive pattern can comprise a polycyclic aromatic compound.

In a light emitting display device according to one embodiment of present disclosure, the metal pattern can comprise at least one of silver, aluminum, magnesium, and calcium.

In a light emitting display device according to one embodiment of present disclosure, the second electrode and the metal pattern can include a same material.

In a light emitting display device according to one embodiment of present disclosure, the refractive pattern and the first capping layer can have different refractive indices.

In a light emitting display device according to one embodiment of present disclosure, the metal pattern and the refractive pattern can be coplanar on the first capping layer and can be in contact with an upper surface of the first capping layer.

In a light emitting display device according to one embodiment of present disclosure, the first capping layer may be an insulating film.

In a light emitting display device according to one embodiment of present disclosure, the second sub-pixel can emit green light.

A light emitting display device according to one embodiment of present disclosure can further include a second capping layer on the metal pattern and the refractive pattern.

A light emitting display device according to one embodiment of present disclosure may further include a third capping layer on the second capping layer and having a refractive index different from that of the second capping layer.

In a light emitting display device according to one embodiment of present disclosure, the metal pattern can be further provided on the refractive pattern of the second sub-pixel.

In a light emitting display device according to one embodiment of present disclosure, the metal pattern of the first sub-pixel can have a first thickness, the metal pattern of the second sub-pixel can have a second thickness. The second thickness can be thinner than the first thickness.

A method of manufacturing a light emitting display device according to one embodiment of present disclosure comprises forming a substrate including a first sub-pixel and a second sub-pixel, forming a light emitting element on the substrate, forming a first capping layer on a second electrode of the light emitting element, forming a refractive pattern containing a polycyclic aromatic compound on the first capping layer of the second sub-pixel, and forming a metal pattern on the first capping layer of the first sub-pixel.

In a method of manufacturing a light emitting display device according to one embodiment of present disclosure, an organic material with low affinity to a metal pattern material may be used to form the refractive pattern.

In a method of manufacturing a light emitting display device according to one embodiment of present disclosure, a polycyclic aromatic compound may be used to form the refractive pattern.

In a method of manufacturing a light emitting display device according to one embodiment of present disclosure, the forming the metal pattern comprises depositing a metal pattern material over an entire surface of the substrate on which the refractive pattern is formed and forming the metal pattern in an area excluding the refractive pattern.

It will be apparent to those skilled in the art that various modifications and variations can be made in the disclosure without departing from the spirit or scope of the disclosure. Thus, it is intended that the disclosure cover such modifications and variations thereof, provided they fall within the scope of the appended claims and their equivalents.

What is claimed is:

1. A light emitting display device comprising:
a substrate comprising a first sub-pixel and a second sub-pixel;
a light emitting element on the substrate;
a first capping layer on a second electrode of the light emitting element;
a metal pattern on the first capping layer and corresponding to the first sub-pixel; and
a refractive pattern on the first capping layer and corresponding to the second sub-pixel.

2. The light emitting display device according to claim 1, wherein the refractive pattern comprises an organic material.

3. The light emitting display device according to claim 1, wherein the refractive pattern comprises a polycyclic aromatic compound.

4. The light emitting display device according to claim 1, wherein the metal pattern comprises at least one of silver, aluminum, magnesium, and calcium.

5. The light emitting display device according to claim 1, wherein the second electrode and the metal pattern include a same material.

6. The light emitting display device according to claim 1, wherein the refractive pattern and the first capping layer have different refractive indices.

7. The light emitting display device according to claim 1, wherein the metal pattern and the refractive pattern are coplanar on the first capping layer and are in contact with an upper surface of the first capping layer.

8. The light emitting display device according to claim 1, wherein the second sub-pixel is configured to emit green light.

9. The light emitting display device according to claim 1, further comprising:
a second capping layer on the metal pattern and the refractive pattern.

10. The light emitting display device according to claim 9, further comprising:
a third capping layer on the second capping layer and having a refractive index different from a refractive index of the second capping layer.

11. The light emitting display device according to claim 1, wherein the metal pattern is further provided on the refractive pattern of the second sub-pixel.

12. The light emitting display device according to claim 11, wherein the metal pattern of the first sub-pixel has a first thickness,
the metal pattern of the second sub-pixel has a second thickness, and
the second thickness is thinner than the first thickness.

13. A method of manufacturing a light emitting display device, the method comprising:
forming a substrate comprising a first sub-pixel and a second sub-pixel;
forming a light emitting element on the substrate;
forming a first capping layer on a second electrode of the light emitting element;
forming a refractive pattern containing a polycyclic aromatic compound on the first capping layer of the second sub-pixel; and
forming a metal pattern on the first capping layer of the first sub-pixel.

14. The method according to claim 13, wherein the forming the metal pattern comprises:
depositing a metal pattern material on an entire surface of the substrate on which the refractive pattern is formed, and
forming the metal pattern in an area excluding the refractive pattern.
